(19) United States
(12) Patent Application Publication
(10) Pub. No.: US 2024/0138061 A1
(43) Pub. Date: Apr. 25, 2024

(54) ENCAPSULATING ELECTRONICS ON FLEXIBLE FLUOROELASTOMER SUBSTRATES

(71) Applicants: Saudi Arabian Oil Company, Dhahran (SA); University of Massachusetts, Boston, MA (US)

(72) Inventors: Sahil P. Wankhede, Boston, MA (US); Xian Du, Boston, MA (US); Ali Al Shehri, Dhahran (SA); Keith William Brashler, Dhahran (SA); Mohammad Al-Ba’adani, Jeddah (SA); Doru Catalin Turcan, Dhahran (SA)

(21) Appl. No.: 18/489,422

(22) Filed: Oct. 18, 2023

Related U.S. Application Data
(60) Provisional application No. 63/380,014, filed on Oct. 18, 2022.

(51) Int. Cl. H05K 1/03; H05K 3/12

(52) U.S. Cl. CPC H05K 1/0393; H05K 3/125; H05K 2203/013; H05K 2203/097; H05K 2203/1305

(57) ABSTRACT

A method of forming a flexible electronic component includes treating a flexible fluoroelastomer substrate to increase the surface energy of the substrate to a specified surface energy. After the treatment, a layer of conductive material is printed with an inkjet printer onto the substrate. After the printing, an encapsulant layer comprising a fluoroelastomer is applied onto the substrate.

### CROSS REFERENCE TO RELATED PATENT APPLICATIONS

This application claims the benefit of U.S. Provisional Application No. 63/380,014, filed Oct. 18, 2022, the contents of which are incorporated by reference herein.

### TECHNICAL FIELD

This disclosure relates to manufacture of electronics.

### BACKGROUND

Flexible electronics can be utilized in a wide variety of application areas such as healthcare, oil and gas industries, marine applications, automobile industries, and others. In some applications, such electronics are exposed to harsh environmental conditions such as, for example, elevated temperatures, alternating pressure, extreme radiation, humidity, salinity, and hazardous chemicals.

### SUMMARY

Certain aspects of the subject matter herein can be implemented as a method of forming a flexible electronic component. The method includes treating a flexible fluoroelastomer substrate to increase the surface energy of the substrate to a specified surface energy. After the treatment, a layer of conductive material is printed with an inkjet printer onto the substrate. After the printing, an encapsulant layer comprising a fluoroelastomer is applied onto the substrate.

Certain aspects of the subject matter herein can be implemented as a flexible electronic component. The electronic component includes a flexible fluoroelastomer substrate, a conductive material applied by inkjet-printing onto the substrate, and an encapsulant layer applied onto the substrate and the conductive material. The encapsulant layer comprises a fluoroelastomer.

Certain aspects of the subject matter herein can be implemented as a method of isolating a conductive pattern on a flexible electronic component. The method includes corona-treating a flexible fluoroelastomer substrate, jetting a conductive ink onto the substrate to form the conductive pattern, and encapsulating the conductive pattern by applying an encapsulant layer comprising a fluoroelastomer onto the ink and the substrate.

Fluoroelastomer encapsulation can play a vital role in safeguarding printed flexible electronics patterns, shielding them from potential damage when subjected to the harsh conditions of fluid environments like crude oil, petroleum, or other hydrocarbon fluids at elevated temperatures.

### DESCRIPTION OF FIGURES

FIG. 1 is a process flow chart of a method for forming a flexible electronic component in accordance with an embodiment of the present disclosure.

FIGS. 2A and 2B are schematic illustrations of a substrate before and after corona treatment in accordance with an embodiment of the present disclosure.

FIG. 3 is a schematic illustration of a flexible electronic component in accordance with an embodiment of the present disclosure.

FIG. 4 is a cross-sectional schematic illustration of a flexible electronic component in accordance with an embodiment of the present disclosure.

FIGS. 5A and 5B are schematic illustrations of printed conductive material patterns in accordance with an embodiment of the present disclosure.

### DETAILED DESCRIPTION

The details of one or more implementations of the subject matter of this specification are set forth in this detailed description, the accompanying drawings, and the claims. Other features, aspects, and advantages of the subject matter will become apparent from this detailed description, the claims, and the accompanying drawings.

Flexible electronics have lately become popular in a wide variety of application areas such as healthcare, oil and gas industries, marine applications, automobile industries, and others. Such applications can expose flexible electronic components to harsh environmental conditions, like elevated temperatures, alternating pressure, extreme radiation, humidity, salinity, hazardous chemicals (such as hydrocarbons), or a blend of these conditions, which can degrade the conductive materials and result in decrease in conductivity.

A conductive circuit pattern can be applied onto a flexible substrate by inkjet printing a conductive material onto the substrate. However, an inkjet printing method of conductive material application can pose several challenges. A mismatch of surface energies of the ink and the substrates can lead to poor ink-substrate interaction and non-uniform ink layer deposition. Nonuniform layer ink deposition can in turn cause cracks in the pattern/circuits that will result in poor conductivity and ultimately undesirable electronic operation.

In accordance with embodiments of the present disclosure, a method of forming a flexible electronic component is disclosed that can result in a uniform disposition of conductive material, with the conductive material effectively from external fluids by the application of a fluoroelastomer encapsulant. In this way, the flexible electronic component can be effectively used in a wider range of operational environments.

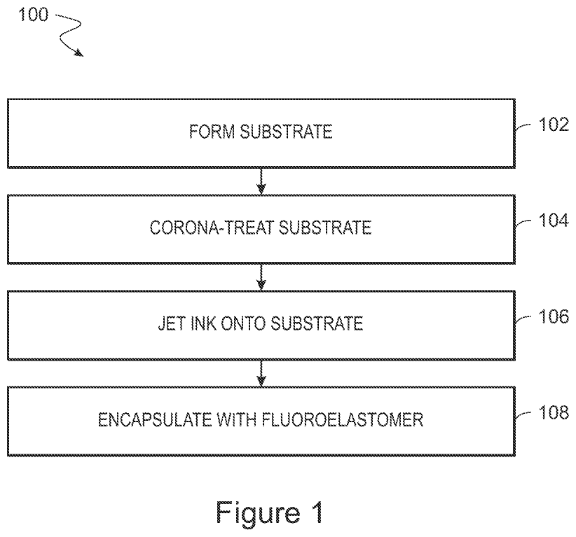

FIG. 1 is a process flow chart of a method 100 for forming a flexible electronic component in accordance with an embodiment of the present disclosure. The method begins at step 102 in which a flexible substrate is formed. In some embodiments, the substrate comprises of a fluoroelastomer (such as, for example, fluorine kautschuk material (FKM) rubber). A suitable FKM can include, for example, VIT-RUB-SHT available from Rubber Sheet Warehouse, having a thickness of 1.57 mm and a maximum operating temperature of 250° Celsius.

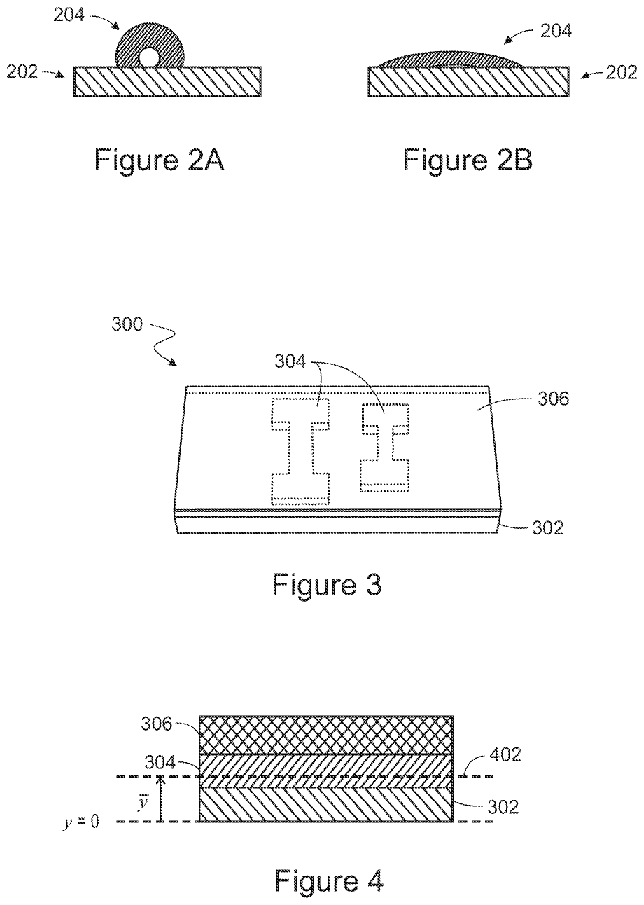

The method then proceeds to step 104 in which the substrate is treated to increase a surface energy of the substrate to a specified surface energy. Surface energy and surface tension are the measurements of intermolecular forces that make up a material. For good quality inkjet printing of the electronics on flexible substrates, in some embodiments, the desired specified surface energy of the substrates after treating is a surface energy that is higher than the surface tension of the conductive ink to be deposited. The most common way to measure the intermolecular forces is by measuring the contact angle. As shown in FIG. 2A, an untreated substrate 202 can be a hydrophobic surface with poor wettability, with a contact angle between a liquid conductive material 204 being greater than 90°. In contrast, with substrate 202 being treated as shown in FIG. 2B to increase its surface energy, the substrate is hydrophilic with better wetting behavior, and the contact angle between the liquid conductive material 204 and substrate 202 being less than 90°. The improved wetting behavior prepares the surface for subsequent processes such as coating, bonding, and painting.

In some embodiments, a suitable substrate treatment method to increase the surface energy to the specified surface energy is plasma treatment with oxygen or nitrogen gas (air corona treatment). Corona treatment is quick, inexpensive, and reduces or eliminates the need for costly and complicated equipment. It can generate discharge at atmospheric pressure and room temperature with no need for a vacuum. Other suitable treatment methods can include chemical treatment methods, such as using 3-mercaptopropyl trimethoxysilane (MPTMS) or flame-pyrolytic surface silicating, which oxidize the surfaces and increase the surface energy by depositing polar groups on the surface. In some embodiments, the surface energy of the substrate is sufficiently high as compared to the surface tension such that no treatment is required prior to inkjet printing.

Proceeding to step 106, the conductive material is deposited onto the substrate. In some embodiments, the material is deposited onto the substrate using inkjet printing. For selecting an ink, important properties like surface tension, viscosity, and resistivity need to be considered. Silver and/or gold nanoparticle (NP) inks can be used due to their high chemical stability, low chemical reactivity, and high electrical conductivity. NP inks are composed of suspended NPs in an organic solvent. Since water is present in the inks, the post-treatment process i.e., sintering is required for solvent evaporation and densification. NP inks can be produced in enormous quantities and dispersed in high concentrations, resulting in good electrical conductivity. These NP inks are vulnerable to the clustering of the suspended particles, which can cause an increase in viscosity and surface tension, consequently clogging the print head nozzles. In some embodiments, to assure good jetting, particle size can be < 1/100 of the size of the nozzle, and all the particles should be uniformly distributed throughout the solution. In some embodiments, a silver conductive ink and adhesive can be suitable due to its high electrical conductivity, chemical stability, thermal stability, and excellent capability of silver oxide to conduct electricity.

Proceeding to step 108, an encapsulant layer is applied onto the substrate and the conductive material, to isolate the conductive material from external fluids and protect the conductive material from harsh environmental conditions. In some embodiments, the encapsulant layer is a fluoroelastomer such as FKM, as defined by ASTM International standard D1418. FKM is widely used in oil and gas, aerospace, military, and chemical processing industries, and other application areas with extreme pressure, temperature, and chemical surroundings. FKM has outstanding performance in an extremely hot and corrosive environment and excellent resistance to aging oxidizers, ozone, oils, and various chemicals. These fluoroelastomers are synthesized through the polymerization of three monomers i.e., vinylidene fluoride, hexafluoropropylene, and tetrafluoroethylene. Fluorine has the highest electronegativity among all halogens; hence it forms extremely strong bonds that make it less prone to degradation as compared to other elastomers. A high proportion of fluorine enables it to maintain its elastomeric properties at temperatures up to 200° C. At room temperature, it has a tensile strength of 11 MPa and the elongation at the fracture is 200%. Thus, printed patterns can be encapsulated using FKM and maintain desirable performance at elevated temperatures in hydrocarbon fluid. FIG. 3 shows an example of a completed flexible electronic component 300 made in accordance with method 100 in accordance with an embodiment of the present invention, showing the conductive material 304 deposited on substrate 302, covered by encapsulant 306.

The thickness of the encapsulation layer to be deposited can be critical since it might affect the stress produced on the conductive pattern. As shown in FIG. 4, in some embodiments, encapsulant layer 306 can be deposited with a thickness (in relation to the thickness of substrate 302 and the layer of conductive material 304) such that the neutral axis 402 passes through the layer of conductive material 304, with the neutral axis being an axis in the cross-section wherein longitudinal stress or strain is zero. Considering the geometry as a composite beam in bending, the neutral axis/neutral plane of a composite beam shown in FIG. 4 can be calculated using the equation (1):

$$\overline{y} = \frac{{A}_{1} \overline{{y}_{1}} + \sum {n}_{i} {A}_{i} {\overline{y}}_{i}}{{A}_{1} + \sum {n}_{i} {A}_{i}} \qquad ( 1 )$$

In equation (1), y̅=neutral axis distance from the datum,

$${n}_{i} = \frac{{E}_{i}}{{E}_{1}} ,$$

A=cross-sectional area, E=Young' s modulus,

$${E}_{plane} = \frac{E}{1 - v} ,$$

and v=Poisson ratio. With the neutral axis so positioned with respect to the conductive material 306, the encapsulant layer 306, and the substrate 302, longitudinal stress or strain can be reduced or eliminated as the component flexes, helping to minimize the cracks and improve the conductivity and overall quality of the circuit.

Laboratory tests of the surface treatment, ink deposition, and encapsulation were done on 2-inch×2-inch (50.8 mm×50.8 mm) substrate samples. A corona treater model BD-20AC (Electro-Technic Products, Inc, USA) was used for the treatment of the surface of the substrates. This treater is a high-frequency generator that produces a high voltage, with a high-frequency spark at the tip of the electrode. The electric field created around the electrode is used for the surface treatment of the polymers. The optimal condition for the surface effect produced by corona treatment depends upon the treatment time, power, and distance between the electrode and surface to be treated. The parameters of the corona treatment for the tests are shown in Table 1.

TABLE 1

| Operating parameter | Range | |
|---|---|---|
| Input voltage | 115 | V,50/60 Hz |
| Current | 0.35 | A |
| Power | 40.25 | W |
| Distance between electrode and surface | 1/8 | in. to 1/4 in. |
| Treatment time | 10 | mins. |

The contact angle of a water droplet was measured using a Rame-Hart goniometer The contact angle before and after corona treatment on an FKM substrate is shown in Table 2:

TABLE 2
Contact angle in degrees

| | Before corona | After corona |
|---|---|---|
| Substrate | treatment | treatment |
| FKM | 102.5 | 52.6 |

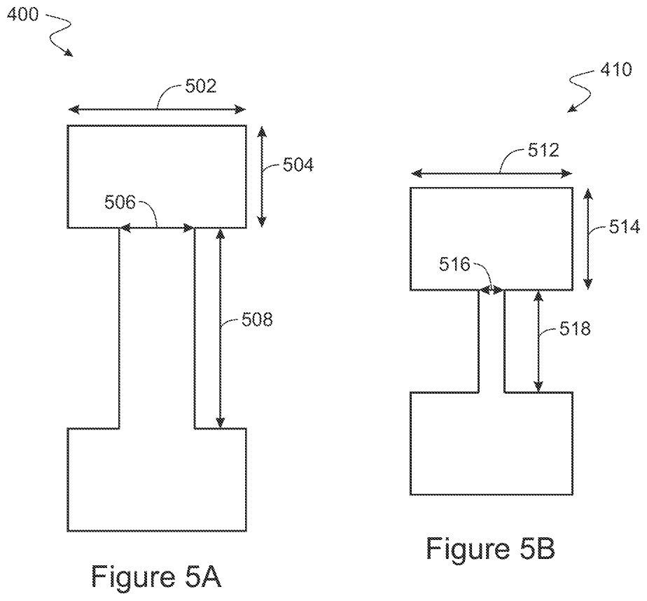

After treatment, the conductive material was deposited, using inkjet printing with intermittent drying. The conductive materials were deposited in two patterns: Pattern A, shown in FIG. 5A, and Pattern B, shown in FIG. 5B. Referring to FIG. 5A, the design dimensions of Pattern A were as follows: length 502 is 4.24 mm, length 504 is 4.44 mm, length 506 is 1.78 mm, and length 508 is 8.88 mm. Referring to FIG. 5B, the design dimensions of Pattern B were as follows: length 512 is 4.28 mm, length 514 is 4.44 mm, length 516 is 0.72 mm, and length 518 is 4.44 mm. To form the patterns, a first layer of the ink was deposited using the inkjet printer and allowed to dry on the printer stage at 60° C. before printing the second layer, with the same procedure for a third layer. After printing three layers the printed pattern was sintered on a hot plate at 150° C. for 60 mins. A commercially available silver (Ag) nanoparticle-based ink Silverj et (DGP-40LT-15C, Sigma Aldrich, USA), was used for the tests. The ink had a surface tension of ˜35-40 dyne/cm (˜35-40 mN/m), viscosity˜10-18 cP (˜10-18 mPa·s) and specific resistivity of 11 μΩ-cm (1.1×10⁻⁷ Ω-m). A drop-on-demand (DOD) piezoelectric type inkjet printer, FUJIFILM Dimatix materials printer DMP-2850 was used for the tests. It has a printable area of 210 mm×315 mm (8.27 in×12.4 in) for substrates having thickness <0.5mm and 0.5-25mm and a vacuum stage to hold the substrate. The temperature of the stage can be varied in the range of 28° C.-60° C.

Inkjet printer parameters like drop spacing, substrate temperature, and nozzle temperature are key to the conductivity of printed patterns. Drop spacing is the center distance between two drops. As the drop spacing increases, the width of the printed pattern decreases, and consequently the electrical resistance increases. The increase in substrate temperature shrinks the width of the pattern and increases the thickness of the pattern which consequently decreases the electrical resistance. This is due to the coffee ring effect caused by Marangoni flow. The rise in nozzle temperature causes an increase in line thickness which increases the cross-sectional area, thus decreasing the electrical resistance. The number of layers printed on the substrate affects the resistance values. The greater the number of printed layers, the lesser the resistance values, however, it will decrease the maximum breakdown strain. Sintering conditions like temperature and duration crucially impact the electrical properties of the printed pattern. Resistance decreases with an increase in sintering temperature. The temperature is governed by the glass transition point (T_{g}) of the polymeric substrates. For PET it is below 150° C. for PDMS, the lowest resistance values were achieved without any damage, at the temperature of 180° C. Thus, printed silver ink can be sintered at a high temperature for solvent evaporation and densification. Table 3 lists the parameters used for printing pattern and sintering conditions (post-printing):

TABLE 3

| | |
|---|---|
| Drop spacing (μm) | 20 |
| Substrate temperature (° C.) | 60 |
| Nozzle temperature (° C.) | 28 |
| Number of layers | 3 |
| Sintering temperature (° C.) | 150 |
| Sintering time (hr.) | 1 |

After sintering, the thickness and area dimensions of the printed patterns were measured and compared to design dimensions and found to be the same as the design dimensions. Table 4 lists the measured average thickness of Pattern A and Pattern B. For each pattern, we measured the thickness at three locations including top, middle, and bottom. Zygo 3D profilometer was used to measure the thickness of the printed layers. The average thickness for the substrate is listed in Table 4.

TABLE 4

| | Average thickness (μm) | |
|---|---|---|
| Substrate | Pattern A | Pattern B |
| FKM | 1.143 | 1.209 |

After sintering, resistance was measured and compared to theoretical resistance. measurements. Theoretical resistance values using Equation 2 were calculated.

$$R = \frac{{ρ}_{l}}{A} = \frac{{ρ}_{l}}{wxt} \qquad ( 2 )$$

In equation (2), R=resistance, ρ=resistivity, A=cross sectional area, l=length of the pattern, w=width of pattern, and t=thickness of pattern. The theoretical resistance values and the results of the resistance measurements are shown in Table 5:

TABLE 5

| | Theoretical (Ω) | | Actual (Ω) | |
|---|---|---|---|---|
| Substrate | Pattern A | Pattern B | Pattern A | Pattern B |
| FKM | 0.75 | 0.4 | 1.8 | 1.6 |

Although theoretical and actual resistance values were not exactly the same, they were found to be comparable for all substrates. Thus, we achieved our first objective of printing flexible conductive patterns using multilayer inkjet printing with intermittent drying. From the table showing higher resistance values, values, actual resistance values are higher than theoretical resistance values. The cause of this can be due to microscopic cracks in the printed pattern. These cracks can be reduced and conductivity can be improved by optimizing parameters i.e., decreasing drop spacing and increasing sintering temperature and duration. However, reducing drop spacing will shrink the size of the geometry and increase the sintering temperature and duration may damage the substrate. Further, conductivity can be improved by using silver nanoparticles (AgNP) of various size distributions. The large-size AgNP forms a conductive path as it starts to melt and contact each other with the rise in sintering time or temperature, whereas the small AgNP packs into the gap created between the larger-size AgNP. Thus, AgNP sinter together to form a 3D conductive network due to high sintering temperature or longer sintering time. However, using different sizes of silver particles might block the inkjet printer nozzle, which will impact the printing process. Thus, considering the scope of our work, the present resistance values could be best achieved.

Before the start of the encapsulation process, the connecting wires are glued on the printed pattern using silver paste (8331D -silver conductive epoxy adhesive, MG Chemicals, USA), then FKM sealant is applied on the periphery of this printed pattern at ambient temperature. Next, the FKM sheet is placed over the top of the bottom sheet and pressed over the FKM caulk forming a permanent seal. Finally, the whole assembly is kept at room temperature for 48 hours to cure. After curing, the samples were immersed at a temperature of 80° C.-180° C. in hydrocarbon fluid (specifically, commercially available hydraulic oil (MAG 1 AW ISO 46). The resistance of each sample was then measured five times at a temperature set point to evaluate the repeatability and robustness of the output resistance values. It was observed that resistance values remained stable at all temperature setpoints thus proving the effectiveness of the encapsulant material in shielding the printed pattern. Table 6 shows the average, minimum, maximum, range, and standard deviation of resistance values (in Ω) for Pattern A and Pattern B submerged in hydraulic oil for a temperature range of 80° C.-180° C.

TABLE 6

| | Pattern A | Pattern B |
|---|---|---|
| Average | 1.84 | 1.2 |
| Maximum | 2.5 | 2.4 |
| Minimum | 1.4 | 1.1 |
| Std. deviation | 0.30 | 0.38 |

The average resistance values slightly increased for the encapsulated sample at elevated temperature which is anticipated due to the property of conductive material as temperature increases resistance values also increase. Fluoroelastomer used as an encapsulant was successful in protecting the printed pattern from the harsh environment without significantly affecting its performance.

### EXAMPLES

In a first aspect, a method of forming a flexible electronic component includes treating a flexible substrate to increase a surface energy of the substrate to a specified surface energy. After the treating, a layer of conductive material is printed with an inkjet onto the substrate. After the printing, an encapsulant layer comprising a fluoroelastomer is applied onto the substrate.

In a second aspect according to the first aspect, the printing the layer of conductive material comprises printing a metallic ink.

In a third aspect according to the first or the second aspect, the metallic ink comprises a silver nanoparticle-based ink.

In a fourth aspect according to any of the first to the third aspect, the encapsulant layer comprises fluorine kautschuk material (FKM).

In a fifth aspect according to any of the first to the fourth aspect, the substrate comprises a fluoroelastomer.

In a sixth aspect according to any of the first to the fifth aspect, a thickness of the substrate, a thickness of the layer of conductive material, and a thickness of the encapsulant layer are such that a neutral axis of the flexible electronic component passes through the layer of conductive material.

In a seventh aspect according to any of the first to the sixth aspect, printing the layer of conductive material comprises printing the conductive material in an electronic circuit pattern.

In an eighth aspect according to any of the first to the seventh aspect, the encapsulant layer and the substrate isolate the conductive material from external fluids.

In a ninth aspect according to any of the first to the eighth aspect, the treating comprises corona treating.

In a tenth aspect according to any of the first to the ninth aspect, wherein, after the treating, the specified surface energy is such that a contact angle between the conductive material and the substrate is less than 90°.

In an eleventh aspect, a flexible electronic component includes a flexible substrate, a conductive material applied by inkjet-printing onto the substrate, and an encapsulant layer applied onto the substrate and the conductive material. The encapsulant layer comprises a fluoroelastomer.

In a twelfth aspect in accordance with the eleventh aspect, the conductive material comprises a metallic ink.

In a thirteenth aspect in accordance with the eleventh or the twelfth aspect, the metallic ink comprises a silver nanoparticle-based ink.

In a fourteenth aspect according to any of the eleventh to the thirteenth aspect, the encapsulant layer comprises FKM.

In a fifteenth aspect according to any of the eleventh to the fourteenth aspect, a thickness of the substrate, a thickness of the layer of conductive material, and a thickness of the encapsulant layer are such that a neutral axis of the flexible electronic component passes through the layer of conductive material.

In a sixteenth aspect according to any of the first to the fifteenth aspect, the layer of conductive material is printed in an electronic circuit pattern.

In a seventeenth aspect according to any of the first to the sixteenth aspect, the encapsulant layer and the substrate isolate the layer of conductive material from external fluids.

In an eighteenth aspect, a method of isolating a conductive pattern on a flexible electronic component includes corona-treating a flexible substrate, jetting a conductive ink onto the substrate to form the conductive pattern, wherein the treating is such that the surface energy is higher than a surface tension of the conductive ink, and encapsulating the conductive pattern by applying an encapsulant layer comprising a fluoroelastomer onto the ink and the substrate.

In a nineteenth aspect according to the eighteenth aspect, the substrate comprises fluorine kautschuk material FKM.

In a twentieth aspect according to the eighteenth or the nineteenth aspect, the treating comprises corona-treating.

What is claimed is:

1. A method of forming a flexible electronic component, the method comprising:
treating a flexible substrate to increase a surface energy of the substrate to a specified surface energy, the flexible substrate comprising a fluoroelastomer;
after the treating, printing, with an inkjet, a layer of conductive material onto the substrate;
after the printing, applying an encapsulant layer onto the substrate and the conductive material, the encapsulant layer comprising a fluoroelastomer.

2. The method of claim 1, wherein the printing the layer of conductive material comprises printing a metallic ink.

3. The method of claim 1, wherein the metallic ink comprises a silver nanoparticle-based ink.

4. The method of claim 1, wherein the encapsulant layer comprises fluorine kautschuk material (FKM).

5. The method of claim 1, wherein the substrate comprises FKM.

6. The method of claim 1, wherein a thickness of the substrate, a thickness of the layer of conductive material, and a thickness of the encapsulant layer are such that a neutral axis of the flexible electronic component passes through the layer of conductive material.

7. The method of claim 1, wherein printing the layer of conductive material comprises printing the conductive material in an electronic circuit pattern.

8. The method of claim 1, wherein the encapsulant layer and the substrate isolate the conductive material from external fluids.

9. The method of claim 1, wherein the treating comprises corona treating.

10. The method of claim 1, wherein, after the treating, the specified surface energy is such that a contact angle between the conductive material and the substrate is less than 90°.

11. A flexible electronic component comprising:
a flexible substrate, the substrate comprising a fluoroelastomer;
a conductive material applied by inkjet-printing onto the substrate; and
an encapsulant layer applied onto the substrate and the conductive material, the encapsulant layer comprising a fluoroelastomer.

12. The flexible electronic component of claim 11, wherein the conductive material comprises a metallic ink.

13. The flexible electronic component of claim 11, wherein the metallic ink comprises a silver nanoparticle-based ink.

14. The flexible electronic component of claim 11, wherein the encapsulant layer comprises fluorine kautschuk material (FKM).

15. The flexible electronic component of claim 11, wherein a thickness of the substrate, a thickness of the layer of conductive material, and a thickness of the encapsulant layer are such that a neutral axis of the flexible electronic component passes through the layer of conductive material.

16. The flexible electronic component of claim 11, wherein the layer of conductive material is printed in an electronic circuit pattern.

17. The flexible electronic component of claim 11, wherein the encapsulant layer and the substrate isolate the layer of conductive material from external fluids.

18. A method of isolating a conductive pattern on a flexible electronic component, the method comprising:
treating a flexible substrate to increase its surface energy, the substrate comprising a fluoroelastomer;
jetting a conductive ink onto the substrate to form the conductive pattern, wherein the surface energy of the flexible substrate after the treating is higher than a surface tension of the conductive ink;
encapsulating the conductive pattern by disposing an encapsulant layer onto the ink and the substrate, the encapsulant layer comprising a fluoroelastomer.

19. The method of claim 18, wherein the substrate comprises fluorine kautschuk material (FKM).

20. The method of claim 18, wherein the treating comprises corona-treating.
